(19) United States
(12) Patent Application Publication
(10) Pub. No.: US 2003/0124873 A1
(43) Pub. Date: Jul. 3, 2003

(54) Method of annealing an oxide film

(76) Inventors: Guangcai Xing, Fremont, CA (US); Lee Luo, Fremont, CA (US); Aihua (Steven) Chen, San Jose, CA (US); Errol Antonio C. Sanchez, Dublin, CA (US); Christopher G. Quentin, Fremont, CA (US); Kuan-Ting (James) Lin, Keelung (TW); Shih-Che (Jeff) Lin, Keelung (TW)

Correspondence Address: APPLIED MATERIALS, INC., 2881 SCOTT BLVD. M/S 2061, SANTA CLARA, CA, 95050, US

(21) Appl. No.: 10/040,614

(22) Filed: Dec. 28, 2001

(51) Int. Cl. H01L 21/31; H01L 21/469

(52) U.S. Cl. 438/770; 438/763; 438/787

(57) ABSTRACT

The present invention is a method of annealing an oxide film. According to the present invention, an oxide film is deposited over a substrate. The oxide film is then annealed by exposing the oxide film to an ambient containing atomic oxygen for a predetermined period of time. In an embodiment of the present invention, the ambient containing atomic oxygen (O) is formed in the chamber by reacting a hydrogen containing gas and an oxygen containing gas together. In another embodiment of the present invention, the ambient containing atomic oxygen (O) is formed by decomposing N₂O.

### BACKGROUND OF THE INVENTION

1. Field of the Invention

The present invention relates to the field of semiconductor integrated circuits and more specifically to a method of annealing a deposited silicon oxide film to improve its quality.

2. Discussion of Related Art

Deposited silicon oxide film, such as high temperature oxides (HTO), formed by chemical vapor deposition (CVD) are used throughout the fabrication of modern integrated circuits. High temperature oxides are used in places of integrated circuits where their film quality can impact the integrated circuit's performance. For example, deposited high temperature oxides are used as inter-poly dielectrics, in oxide-nitride-oxide (ONO) composite films for nonvolatile memories, and in the fabrication of sidewall spacers in metal oxide semiconductor (MOS) transistors. Unfortunately, as deposited high temperature oxide films usually suffer from quality issues, such as dangling bonds, high hydrogen (H) content (3-4-atomic percent hydrogen) and low density. Generally, as deposited HTO films are annealed with N₂ or O₂ to improve their quality. Unfortunately, present methods of annealing HTO films are inefficient at improving the quality of the as deposited oxide film.

Thus, what is needed is a method for annealing an as deposited oxide film to improve its quality in an efficient manner.

### SUMMARY OF THE INVENTION

The present invention is a method of annealing an oxide film. According to the present invention, an oxide film is deposited over a substrate. The oxide film is then annealed by exposing the oxide film to an ambient containing atomic oxygen for a predetermined period of time. In an embodiment of the present invention, the ambient containing atomic oxygen (O) is formed in the chamber by reacting a hydrogen containing gas and an oxygen containing gas together. In another embodiment of the present invention, the ambient containing atomic oxygen (O) is formed by decomposing N₂O.

### BRIEF DESCRIPTION OF THE DRAWINGS

FIG. 1 is an illustration of a flowchart of a method for forming an oxide film in accordance with an embodiment of the present invention.

FIG. 2 is an illustration of a flowchart illustrating a method of forming an oxide-nitride-oxide (ONO) composite film in accordance with an embodiment of the present invention.

FIG. 3 is an illustration of a cluster tool having an oxide deposition chamber, an anneal chamber, and a nitride deposition chamber which can be used to form an oxide-nitride-oxide (ONO) film in accordance with an embodiment of the present invention.

FIGS. 4A-4E are illustrations of cross-sectional views showing the formation of a nonvolatile memory device in accordance with an embodiment of the present invention.

FIG. 5A is an illustration of a rapid thermal heating apparatus which can be used to form an ambient having an atomic oxygen in accordance with an embodiment of the present invention.

FIG. 5B is an illustration of the life source placement in the rapid thermal heating apparatus of FIG. 5A.

FIG. 6 is a flowchart which illustrates a rapid thermal anneal process which utilizes an insitu steam generation (ISSG) process to form an atomic oxygen containing ambient.

### DETAILED DESCRIPTION OF THE PRESENT INVENTION

The present invention is a novel method of annealing an oxide film. In the following description numerous specific details are set forth in order to provide a thorough understanding of the present invention. One of ordinary skill in the art will appreciate that these specific details are not necessary in order to practice the present invention. In other instances, well-known semiconductor process techniques and equipment have not been set forth in particular detail in order to not unnecessarily obscure the present invention.

The present invention is a novel method of forming a high quality oxide film. According to the present invention, a deposited oxide is annealed with an ambient containing atomic oxygen. The atomic oxygen ambient anneal of the present invention improves the quality of the deposited oxide film by reducing defects, reducing dangling bonds, reducing the hydrogen content and by increasing the density of the film.

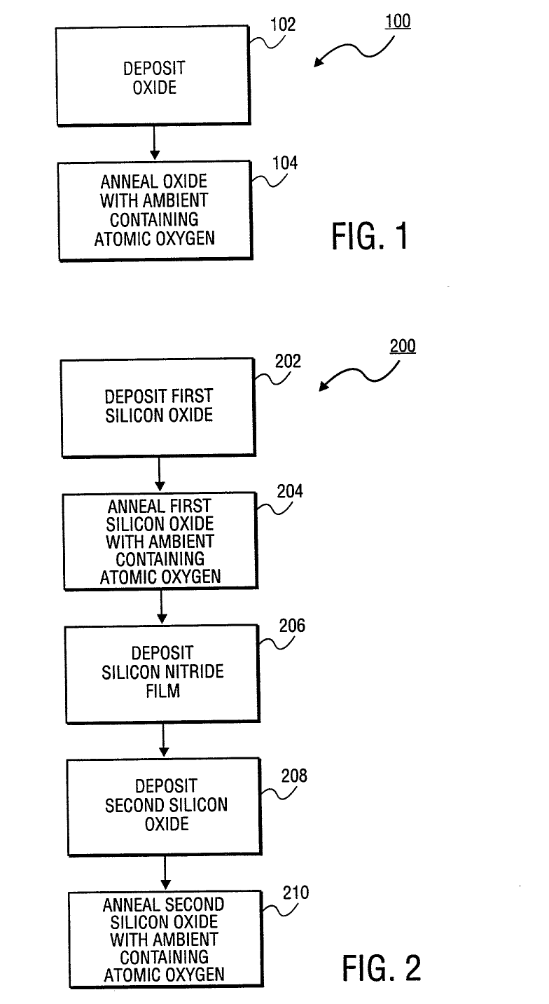

As shown in FIG. 1, is a flowchart 100 which sets forth a method of forming an oxide film in accordance with the present invention. The first step, as set forth in block 102 of flowchart 100, is to deposit an oxide film, such as a silicon oxide film over a substrate. A substrate for the purpose of the present invention is the body or structure upon which the oxide film of the present invention is formed. The substrate will typically be a silicon wafer which includes a monocrystalline silicon substrate in and on which active devices, such as transistors and capacitors are formed. It is to be appreciated that the substrate of the present invention can be other types of semiconductor substrates, such as but not limited to gallium arsenide substrates and silicon on insulator (SOI) substrates. The oxide film of the present invention can be used in many different applications or functions in the fabrication of an integrated circuit. For example, the oxide film can be used as an active dielectrics, such as capacitors or gate dielectrics. Additionally, the oxide film of the present invention can be used to form sidewall spacers for a transistor or used as an interlayer dielectric to electrically isolated and separate metal interconnects used to electrically couple active devices together into functional circuits.

In an embodiment of the present invention, the oxide film is a silicon oxide or silicon oxynitride film. In an embodiment of the present invention, the oxide film is high temperature oxide (HTO), such as a silicon oxide or silicon oxynitride film deposited by thermal chemical vapor deposition. A high temperature silicon dioxide film can be deposited by thermal decomposition of a process gas mix comprising a silicon source gas, such as silane (SiH₄) or dichlorosilane (SiH₂Cl₂) and an oxygen source gas, such as N₂O or O₂ at a temperature between 700-800° C. at a deposition pressure ranging from militorrs to 300 torr. A silicon oxynitride film can be formed by also including ammonia (NH3) in the process gas mix.

In an alternative embodiment of the present invention, the oxide film can be a low temperature oxide (LTO) deposited by thermal chemical vapor deposition utilizing a silicon source gas, such silane (SiH₄) or dichlorosilane (SiH₂Cl₂) and an oxygen containing source gas, such as N₂O at a deposition temperature between 375-450° C. with about 400° C. being preferred. In yet another embodiment of the present invention, the oxide film can be formed by sub-atmospheric chemical vapor deposition (SACVD).

It is to be appreciated that the oxide film need not necessarily be a silicon oxide or silicon oxynitride film, but can also be other types of dielectric films, such as a high K dielectric, such as PZT and metal oxide dielectrics, such as but not limited to tantalum pentaoxide (Ta₂O₅) and titanium oxide (TiO). The oxide film can be deposited to any thickness desired for a given application. In an embodiment of the present invention, the oxide film is deposited to a thickness between 30-5000 Å.

Any well-known deposition apparatus, such as a batch type furnace or a single wafer cold wall reactor can be used to form the oxide film. In an embodiment of the present invention, a single wafer cold wall reactor having a resistively heated susceptor upon which the wafer or substrate rest during deposition, such as the Applied Materials OxZgen deposition chamber is utilized to deposit the oxide film in a thermal chemical vapor deposition (CVD) process.

After deposition “as deposited” oxides are typically of poor quality in that they can contain an unacceptable amount of defects, can contain silicon dangling bonds, can contain a high hydrogen content (H) (i.e., greater than 1 atomic percent) and low density. It is to be noted that high temperature oxide films deposited by thermal chemical vapor deposition in a single wafer cold wall reactor can have an unacceptably high between 3-4% hydrogen concentration due to the high deposition rates (60-3000 Å per minute) necessary for depositing an oxide film in a manufactural amount of time.

Next, as set forth in block 104 of flowchart 100 of FIG. 1, the deposited oxide film is annealed in an ambient containing atomic oxygen (O) atoms. Atomic oxygen (O) atoms are very reactive so that they provide a means for annealing the as deposited oxide in a highly efficient manner. The ambient must contain a sufficient amount of atomic oxygen to suitably treat the oxide film. Additionally, the oxide film is annealed with atomic oxygen for a period of time sufficient to improve the quality of the oxide film. In an embodiment of the present invention, oxide film is annealed with atomic oxygen while heating the substrate to a temperature of at least 600° C. In an embodiment of the present invention, the oxide film is annealed for a period of time with is greater than 30 seconds and which is preferably between 30-60 seconds. In an embodiment of the present invention, the oxide film is annealed with atomic oxygen until the hydrogen (H) concentration in the “as deposited film” is reduced to an acceptable level.

Atomic oxygen have a very short lifetime in that they quickly recombine with other elements or molecules in the ambient. For example, oxygen atoms quickly react with other oxygen atoms to form O₂ or with NO molecules to form N₂O. Accordingly, the atomic oxygens in an embodiment of the present invention are created very dose to the surface of the oxide film which they are annealing. In an embodiment of the present invention, the atomic oxygen is created within a distance from the substrate which is less than the distance the average atomic oxygen atom can travel before it recombines under process conditions used to create the atomic oxygen (O). Alternatively, one can form the atomic oxygen (O) at a distance further away from the oxide film, and utilize process conditions, such as low pressure, to increase the average lifetime of the atomic oxygen so that they can reach the surface of the oxide film before recombining.

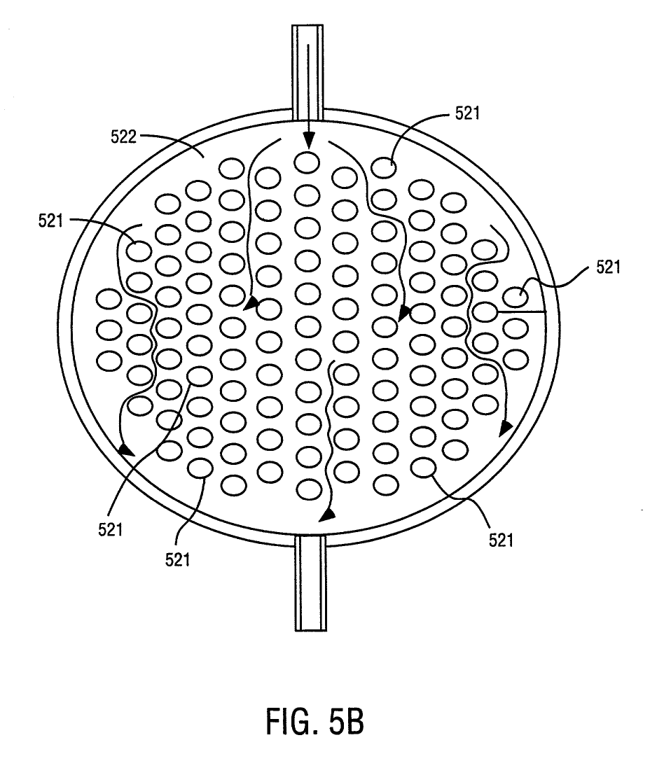

In a preferred embodiment of the present invention, the ambient containing atomic oxygen is created by an insitu steam generation (ISSG) process. In an insitu steam generation process, an oxygen containing gas, such as but not limited to O₂ or N₂O and a hydrogen containing gas, such as H₂ are thermally reacted together in a cold wall reactor to form water (H₂O) vapor in the same chamber in which the substrate having the oxide film is located. The reaction of a hydrogen containing gas and an oxygen containing gas generates an ambient containing H₂O as well as very short lifetime intermediate species, such as atomic oxygen (O) atoms and OH molecules. The reaction of the hydrogen containing gas and oxygen containing gas preferably occurs in a cold wall reactor, so that only the substrate or wafer is sufficiently heated to initiate the reaction of the hydrogen containing gas and oxygen containing gas. In this way, the creation of the atomic oxygen atoms is limited to the area directly above, of the heated substrate. In an embodiment of the present invention, the oxide film is annealed with an ISSG created ambient in a cold wall reactor, such as the Applied Materials RTP Centura with a honeycomb source, such as illustrated in FIGS. 5A and 5B while the wafer is heated to a temperature between 600-1200° C. and preferably at about 900° C. for between 30-60 seconds.

As will be discussed in greater detail below in an ISSG process, the hydrogen source gas and oxygen source gas concentration as well as deposition pressure can be utilized to create an ambient with a large number of atomic oxygen to anneal the oxide film. In an embodiment of the present invention, the reaction of the hydrogen containing gas and oxygen containing gas occurs at a reduced chamber pressure, less than atmospheric, and preferably at a chamber pressure of less than 30 torr, and ideally less than 15 torr. A low pressure reaction of the hydrogen containing gas and oxygen containing gas is thought to create more atomic oxygen and/or increase the lifetime of the atomic oxygen which thereby increases efficiency of the anneal process of the present invention. In an embodiment of the present invention, when a cold wall reactor is utilized, it has been found that a reduced chamber pressure of between 5-15 torr during the reaction of the hydrogen containing gas and the oxygen containing gas yields the most efficient anneal. More detail on the ISSG anneal will be described below.

In alternative embodiment of the present invention, the ambient containing atomic oxygen is formed by the thermal decomposition of nitrous oxide (N₂O) in a cold wall rapid thermal reactor, such as an Applied Materials RTP Centura with a Honeycomb source, such as illustrated in FIGS. 5A and 5B. In this method of the present invention, N₂O is thermally decomposed by heating the substrate to a temperature above 600° C. and preferably above 800° C. A temperature of approximately 900° C. has been found to provide good results. N₂O thermally decomposes into N₂ molecules, atomic oxygen atoms(O), NO molecules, and O₂ molecules. Since a cold wall reactor is utilized, heat from the substrate is the only sufficiently hot region of the chamber to cause the decomposition of N₂O. As such, N₂O only decomposes directly over the oxide film formed over the substrate and within a distance that the short-lived atomic oxygen (O) can suitably anneal the dielectric film. The thermal decomposition of the N₂O can occur at atmospheric pressure or at reduced pressure between less than atmospheric pressure and 5 torr and preferably at a pressure of about 100 torr

In yet another embodiment of the present invention, ultraviolet (UV) light is utilized to thermally decompose N₂O or oxygen (O₂) gas to form atomic oxygen. In such a case the UV light is irradiated at the area directly over the substrate so that the atomic oxygen are created in the region directly over the substrate.

After a sufficient annealing of the oxide film with the atomic oxygen containing ambient of the present invention, the formation of the oxide film in accordance with the present invention is complete.

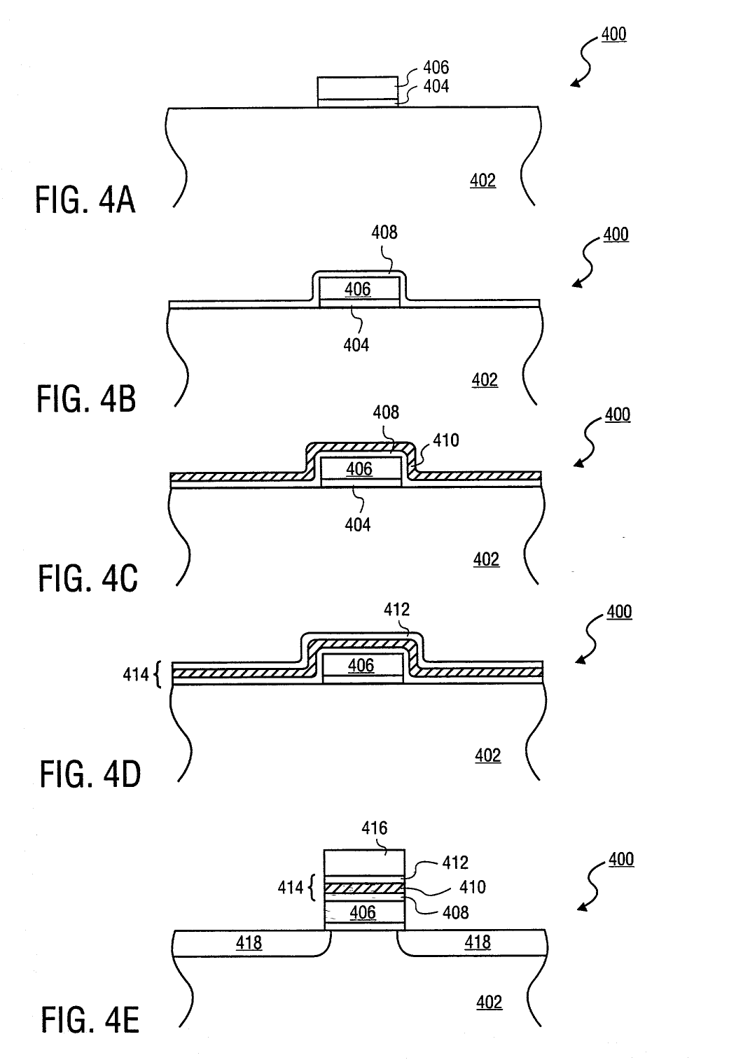

In an embodiment of the present invention, the oxide film of the present invention is formed in a cluster tool, such as cluster tool 300 as shown in FIG. 3. Cluster tool 300 includes a transfer chamber 302 having a wafer handling device 304, such as a robot, contained therein. Coupled to the transfer chamber 302 is a load lock or plurality of load locks 306 for transferring wafers into and out of transfer chamber 302 of cluster tool 300. Coupled to transfer chamber 302 is an oxide deposition chamber 308 where an oxide film is deposited. In an embodiment of the present invention, the oxide deposition chamber 308 is a single wafer cold wall reactor having a resistively heated susceptor upon which the wafer or substrate rest during deposition, such as the Applied Materials OxZgen deposition chamber.

Additionally, also coupled to transfer chamber 302 is annealed chamber 310 in which an ambient containing atomic oxygen is produced to anneal the oxide film formed in deposition chamber 308. In an embodiment of the present invention, the anneal chamber 310 is a single wafer cold wall rapid thermal processor (RTP), such as the Applied Materials RTP Centura having a Honeycomb source, such as illustrated in FIGS. 5A and 5B. Robot 304 is able to move wafers from load locks 306 through transfer chamber 302 to the various chambers coupled to transfer chamber 302. Transfer chamber 302 is generally keep at a reduced pressure with an inert ambient, such as N2, so that wafers are not contaminated or oxidized when transferred between various process chambers coupled to transfer chamber 302. In applications when a composite oxide/silicon nitride composite film is desired, such as in the case when manufacturing oxide-nitride-oxide (ONO) composite dielectric, a silicon nitride deposition chamber 312 can be coupled to cluster tool 300 as shown in FIG. 3. In an embodiment of the present invention, nitride deposition chamber 312 is a single wafer cold wall reactor having a resistively heated susceptor upon which the substrate rest during deposition, such as the Applied Materials SiNgen Chamber.

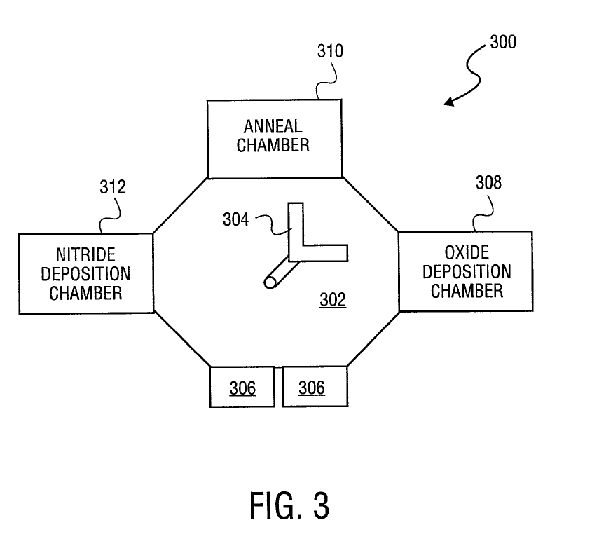

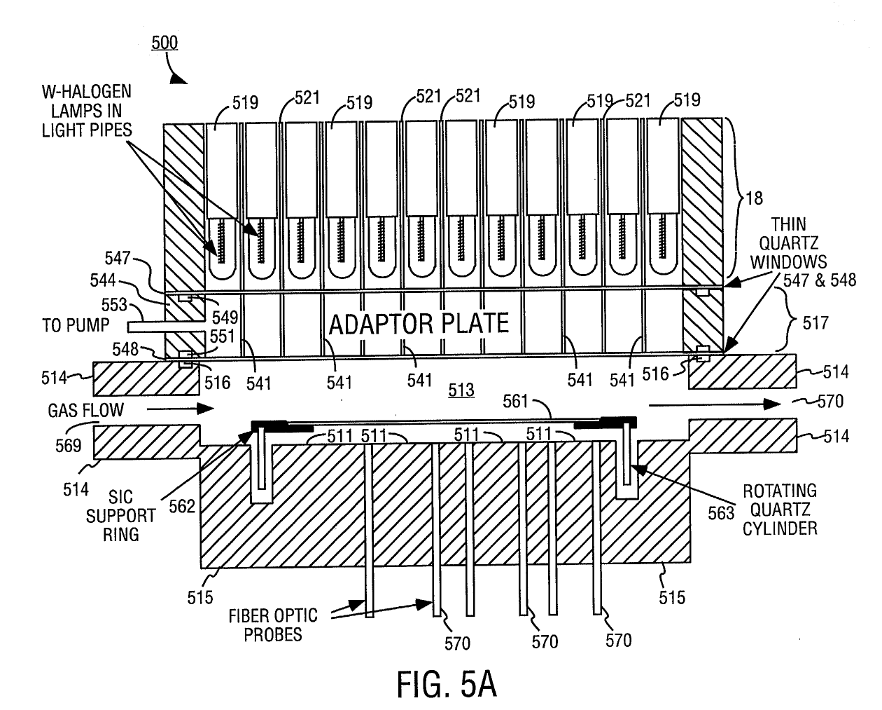

In an embodiment of the present invention the oxide film formation process of the present invention is used to form a composite oxide-nitride-oxide (ONO) film. An ONO film is typically used as an active dielectric layer between a floating gate and a control gate of a nonvolatile memory device, such as a flash memory device. FIG. 2 illustrates a flowchart 200 which sets forth a method of forming an ONO composite film stack in accordance with an embodiment of the present invention. The method of forming an ONO composite film stack in accordance with the present invention will be illustrated with respect to the fabrication of a flash nonvolatile memory device as illustrated in FIGS. 4A-4E. It is to be appreciated that the use of an ONO composite film stack is not limited to nonvolatile memory devices and can be used in other areas, such as but not limited to the formation of composite spacers and composite capacitors. In the fabrication of a nonvolatile memory device, a substrate 400 having a doped single crystalline silicon substrate 402 is provided. A gate dielectric layer 404 is formed on the single crystalline silicon substrate 402 and a floating gate electrode 406, such as n type polysilicon floating gate electrode is formed on the gate dielectric 404 as shown in FIG. 4A.

In an embodiment of the present invention, cluster tool 300 is utilized to form the ONO composite film stack. Accordingly, substrate 400 would be removed from load lock 306 by wafer handling device 304 and brought into transfer chamber 302. Wafer 400 would then be placed in the oxide deposition chamber 308 and the chamber sealed. An oxide film 408 would then be formed over substrate 400 including on top of monocrystalline silicon substrate 402 as well as over and around gate electrode 406 as shown in FIG. 4B. In an embodiment of the present invention, the oxide film is a silicon oxide or silicon oxynitride film formed by a high temperature oxide (HTO) process as described above. In an embodiment of the present invention, oxide film 408 is formed to a thickness between 30-100 Å. The “as deposited” oxide 408 will typically have at least 1-2 atomic percent hydrogen and typically between 3-4 atomic percent hydrogen therein.

Next, as set forth in block 204 of flowchart 200, silicon oxide film 408 is annealed with an ambient containing atomic oxygen. Accordingly, substrate 400 is removed from oxide deposition chamber 308 by wafer handling device 304 brought into transfer chamber 302 and placed into anneal chamber 310. Oxide film 408 is then annealed with an ambient containing atomic oxygen as set forth in block 204 of FIG. 2. In an embodiment of the present invention, oxide film 408 is annealed with atomic oxygen atoms created by an ISSG ambient. In an embodiment of the present invention, the oxide film is annealed in an ISSG ambient at a temperature of 900° C. for between 30-60 seconds. In an embodiment of the present invention, the ISSG ambient is made with a gas mix consisting of hydrogen (H₂) gas and oxygen (O₂) gas and a temperature of at least 900° C. and at a total pressure of between 5-15 torr with 10 torr being preferred. In an embodiment of the present invention, the ISSG ambient is created with a process gas mix comprising between 1-33% H₂ and the remainder O₂, and in a preferred embodiment utilizes a process gas mix comprising approximately 10% H₂ and the remainder O₂. In an alternative embodiment of the present invention, the oxide film 408 is annealed for between 30-60 seconds with an ambient containing atomic oxygen (O) created near the surface of the oxide film 408 by the thermal decomposition of N₂O at a temperature greater than 600° C. and preferably greater than 800° C. After oxide film 408 has been sufficiently annealed with atomic oxygen, substrate 400 is removed from the anneal chamber 310 by wafer handling device 302 and placed in nitride deposition chamber 312.

Next, as set forth in block 206 of flowchart 200 of FIG. 2, a silicon nitride film 410 is blanket deposited over annealed oxide film 408 as shown in FIG. 4C. Silicon nitride layer 410 can be formed to a thickness between 30-100 Å. A silicon nitride film can be formed by thermal chemical vapor deposition utilizing a silicon source gas, such as dichlorosilane and ammonia at a deposition temperature between 600-800° C. and a pressure between 100-500 torr. After a sufficient silicon nitride film 410 has been formed, wafer 400 is removed from nitride chamber 312 by robot 304 and placed into oxide deposition chamber 308.

Next, as set forth in block 208 of flowchart 200, a second oxide film 412 is deposited over substrate 400 and onto silicon nitride layer 410 as shown in FIG. 4D. In an embodiment of the present invention, oxide film 412 is a silicon oxide or silicon oxynitride film formed by a high temperature oxide process as described above. Oxide film 412 can be formed to a thickness between 30-100 Å.

Next, as set forth in block 208 of FIG. 2, substrate 400 is removed from oxide deposition chamber 308 by robot 304 and brought through transfer chamber 302 and placed into anneal chamber 310. The oxide film 412 is then annealed with an ambient containing atomic oxygen (O) as set forth in block 210 of FIG. 2. In an embodiment of the present invention, oxide film 412 is annealed with atomic oxygen created during the formation of an ISSG ambient as described above. In an alternative embodiment of the present invention, the oxide film 412 is annealed with atomic oxygen created by the thermal decomposition of N₂O molecules near the surface of the oxide film as described above. At this point, a high quality ONO composite dielectric film 414 has been fabricated.

Standard processing technique can now be used to complete the fabrication of the nonvolatile memory device. For example, a top control gate material, such as doped polycrystalline silicon film would be blanket deposited over composite film 414 and then the control gate material and the composite film stack 414 would be patterned with well-known photolithography and etching techniques to form a control gate 416 which is separated from floating gate 406 by high quality ONO dielectric 414. At this point, well-known doping techniques, such as ion-implantation would be utilized to form source/drain regions 418 in monocrystalline substrate 402. Source/drain regions 418 would be of opposite conductivity type then the doping of monocrystalline substrate 402. This would complete the fabrication of a nonvolatile memory device having a high quality ONO dielectric film.

It is to be appreciated that the above referenced process utilize an atomic oxygen anneal for both the first oxide dielectric 408 as well as the second oxide dielectric 412. It is to be appreciated that one is able to form an improved ONO dielectric film by annealing with atomic oxygen only one of the silicon oxide dielectrics, either 408 or 412. Additionally, it is to be appreciated that the present invention can be utilized to form an oxide nitride composite stack where only one of the oxide films 408 or 412 is formed. Such a use of an oxide nitride film stack may be in the fabrication of composite sidewall spacers.

In an embodiment of the present invention, an insitu steam generation (ISSG) ambient is used to anneal oxide film. In an ISSG process, an ambient comprising steam (H₂O) is formed in the same chamber as which the substrate to be annealed is located (i.e., steam is formed insitu with the substrate). According to the ISSG anneal method of the present invention a reactant gas mixture comprising a hydrogen containing gas, such as but not limited to H₂ and NH₃, and an oxygen containing gas, such as but not limited to O₂ and N₂O, is fed into a reaction chamber in which a substrate to be annealed is located. The oxygen containing gas and the hydrogen containing gas are caused to react to form moisture or steam (H₂O) in the reaction or anneal chamber in which the substrate to be annealed is located. During the reaction to form H₂O molecules intermediate species, such as atomic oxygen (O) and OH are also created. The reaction of the hydrogen containing gas and the oxygen containing gas is ignited or catalyzed by heating the wafer to a temperature sufficient to cause the steam generation reaction. The ambient created by reacting the oxygen containing gas and hydrogen containing gas is used to anneal the oxide film. Because the heated wafer is used as the ignition source for the reaction, the moisture generation reaction occurs in close proximity to the wafer surface. Reactant gas concentrations and partial pressures are controlled so as to prevent spontaneous combustion within the chamber. By keeping the chamber partial pressure of the reactant gas mixture at less than or equal to 150 torr during the reaction, any reactant gas concentration may be utilized to form moisture without causing spontaneous combustion. The insitu moisture generation process of the present invention preferably occurs in a reduced pressure single wafer chamber of a rapid thermal processor. A rapid thermal anneal utilizing insitu steam generation is ideally suited for annealing an oxide film in the formation of modern ultra high density integrated circuits.

The ISSG anneal of the present invention is preferably carried out in a rapid thermal heating apparatus, such as but not limited to, the Applied Materials, Inc. RTP Centura with a Honeycomb Source. Another suitable rapid thermal heating apparatus and its method of operation is set forth in U.S. Pat. No. 5,155,336 assigned to the Assignee of the present application. Additionally, although the insitu moisture generation reaction of the present invention is preferably carried out in a rapid thermal heating apparatus, other types of thermal reactors may be utilized such as the Epi or Poly Centura single wafer “cold wall” reactor by Applied Materials used to form high temperature films (HTF) such as epitaxial silicon, polysilicon, oxides and nitrides.

FIGS. 5A and 5B illustrate a rapid thermal heating apparatus 500 which can be used to carry out the ISSG anneal process of the present invention. Rapid thermal heating apparatus 500, as shown in FIG. 5A, includes an evacuated process chamber 513 enclosed by a sidewall 514 and a bottom wall 515. Sidewall 514 and bottom wall 515 are preferably made of stainless steel. The upper portion of sidewall 514 of chamber 513 is sealed to window assembly 517 by “O” rings 516. A radiant energy light pipe assembly 518 is positioned over and coupled to window assembly 517. The radiant energy assembly 518 includes a plurality of tungsten halogen lamps 519, for example Sylvania EYT lamps, each mounted into a light pipe 521 which can be a stainless steel, brass, aluminum or other metal.

A substrate or wafer 561 is supported on its edge in side chamber 513 by a support ring 562 made up of silicon carbide. Support ring 562 is mounted on a rotatable quartz cylinder 563. By rotating quartz cylinder 563 support ring 562 and wafer 561 can be caused to rotate. An additional silicon carbide adapter ring can be used to allow wafers of different diameters to be processed (e.g., 150 mm, 200 mm and 300 mm). The outside edge of support ring 562 preferably extends less than two inches from the outside diameter of wafer 561. The volume of chamber 513 is approximately two liters.

The bottom wall 515 of apparatus 500 includes a gold coated top surface 511 for reflecting energy onto the backside of wafer 561. Additionally, rapid thermal heating apparatus 500 includes a plurality of fiber optic probes 570 positioned through the bottom wall 515 of apparatus 500 in order to detect the temperature of wafer 561 at a plurality of locations across its bottom surface. Reflections between the backside of the silicon wafer 561 and reflecting surface 511 create a blackbody cavity which makes temperature measurement independent of wafer backside emissivity and thereby provides accurate temperature measurement capability.

Rapid thermal heating apparatus 500 includes a gas inlet 569 formed through sidewall 514 for injecting process gas into chamber 513 to allow various processing steps to be carried out in chamber 513. Coupled to gas inlet 569 is a source, such as a tank, of oxygen containing gas such as O₂ and a source, such as a tank, of hydrogen containing gas such as H₂. Positioned on the opposite side of gas inlet 569, in sidewall 514, is a gas outlet 568. Gas outlet 568 is coupled to a vacuum source, such as a pump, to exhaust process gas from chamber 513 and to reduce the pressure in chamber 513. The vacuum source maintains a desired pressure while process gas is continually fed into the chamber during processing.

Lamps 519 include a filament wound as a coil with its axis parallel to that of the lamp envelope. Most of the light is emitted perpendicular to the axis towards the wall of the surrounding light pipe. The light pipe length is selected to at least be as long as the associated lamp. It may be longer provided that the power reaching the wafer is not substantially attenuated by increased reflection. Light assembly 518 preferably includes 187 lamps positioned in a hexagonal array or in a “honeycomb shape” as illustrated in FIG. 5B. Lamps 519 are positioned to adequately cover the entire surface area of wafer 561 and support ring 562. Lamps 519 are grouped in zones which can be independently controlled to provide for extremely uniform heating of wafer 561. Heat pipes 521 can be cooled by flowing a coolant, such as water, between the various heat pipes. The radiant energy source 518 comprising the plurality of light pipes 521 and associated lamps 519 allows the use of thin quartz windows to provide an optical port for heating a substrate within the evacuative process chamber.

Window assembly 517 includes a plurality of short light pipes 541 which are brazed to upper/lower flange plates which have their outer edges sealed to an outer wall 544. A coolant, such as water, can be injected into the space between light pipes 541 to serve to cool light pipes 541 and flanges. Light pipes 541 register with light pipes 521 of the illuminator. The water cooled flange with the light pipe pattern which registers with the lamp housing is sandwiched between two quartz plates 547 and 548. These plates are sealed to the flange with “O” rings 549 and 551 near the periphery of the flange. The upper and lower flange plates include grooves which provide communication between the light pipes. A vacuum can be produced in the plurality of light pipes 541 by pumping through a tube 553 connected to one of the light pipes 541 which in turn is connected to the rest of the pipes by a very small recess or groove in the face of the flange. Thus, when the sandwiched structure is placed on a vacuum chamber 513 the metal flange, which is typically stainless steel and which has excellent mechanical strength, provides adequate structural support. The lower quartz window 548, the one actually sealing the vacuum chamber 513, experiences little or no pressure differential because of the vacuum on each side and thus can be made very thin. The adapter plate concept of window assembly 517 allows quartz windows to be easily changed for cleaning or analysis. In addition, the vacuum between the quartz windows 547 and 548 of the window assembly provides an extra level of protection against toxic gasses escaping from the reaction chamber.

Rapid thermal heating apparatus 500 is a single wafer reaction chamber capable of ramping the temperature of a wafer 561 or substrate at a rate of 25-100° C./sec. Rapid thermal heating apparatus 500 is said to be a “cold wall” reaction chamber because the temperature of the wafer during the anneal process is at least 400° C. greater than the temperature of chamber sidewalls 514. Heating/cooling fluid can be circulated through sidewalls 514 and/or bottom wall 515 to maintain walls at a desired temperature. For an anneal process utilizing the insitu steam generation of the present invention, chamber walls 514 and 515 are maintained at a temperature greater than room temperature (23° C.) in order to prevent condensation. Rapid thermal heating apparatus 500 is preferably configured as part of a “cluster tool” which includes a load lock and a transfer chamber with a robotic arm.

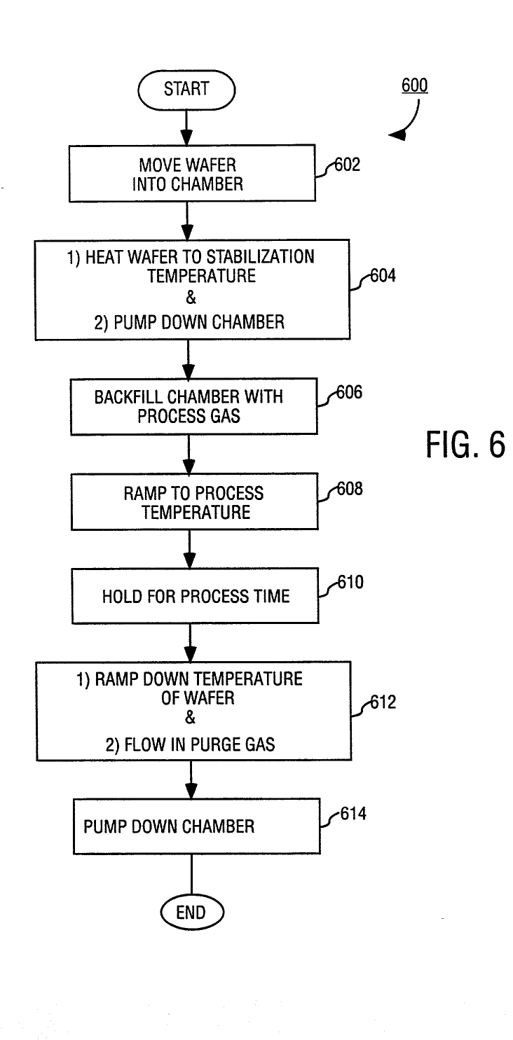

A method of generating an insitu steam ambient for a rapid thermal annealing process according to an embodiment of the present invention is illustrated in flow chart 600 of FIG. 6. The method of the present invention will be described with respect to an insitu steam generation process in the rapid thermal heating apparatus illustrated in FIGS. 5A and 5B.

The first step according to the present invention, as set forth in block 602, is to move a wafer or substrate, such as wafer 561 into vacuum chamber 513. As is typical with modern cluster tools, wafer 561 will be transferred by a robot arm from a load lock through a transfer chamber and placed face up onto silicon carbide support ring 562 located in chamber 513 as shown in FIG. 5A. Wafer 561 will generally be transferred into vacuum chamber 513 having a nitrogen (N2) ambient at a transfer pressure of approximately 20 torr. Chamber 513 is then sealed.

Next, as set forth in block 604 of flow chart 600, the pressure in chamber 513 is further reduced by evacuating the nitrogen (N₂) ambient through gas outlet 570. Chamber 513 is evacuated to a pressure to sufficiently remove the nitrogen ambient. Chamber 513 is pumped down to a prereaction pressure less than the pressure at which the insitu moisture generation is to occur, and is preferably pumped down to a pressure of less than 1 torr.

Simultaneous with the prereaction pump down, power is applied to lamps 519 which in turn irradiate wafer 561 and silicon carbide support ring 562 and thereby heat wafer 561 and support ring 562 to a stabilization temperature. The stabilization temperature of wafer 561 is less than the temperature (reaction temperature) required to initiate the reaction of the hydrogen containing gas and oxygen containing gas to create the insitu steam ambient generation. The stabilization temperature in the preferred embodiment of the present invention is approximately 500° C.

Once the stabilization temperature and the prereaction pressure are reached, chamber 513 is backfilled with the desired mixture of process gas as set forth in block 606 of flowchart 600. The process gas includes a reactant gas mixture comprising two reactant gasses: a hydrogen containing gas and an oxygen containing gas, which can be reacted together to form water vapor (H₂O) at temperatures between 400-1250° C. The hydrogen containing gas, is preferably hydrogen gas (H₂), but may be other hydrogen containing gasses such as, but not limited to, ammonia (NH₃), deuterium (heavy hydrogen) and hydrocarbons such as methane (CH₄). The oxygen containing gas is preferably oxygen gas (O₂) but may be other types of oxygen containing gases such as but not limited to nitrous oxide (N₂O). Inert gasses, such as but not limited to nitrogen (N2), and Argon (Ar) may be included in the process gas mix if desired. In an embodiment of the present invention the process gas mix only includes the reactant gas mixture (i.e., only includes a hydrogen containing gas and a oxygen containing gas). The oxygen containing gas and the hydrogen containing gas are preferably mixed together in chamber 613 to form the reactant gas mixture.

In the present invention the partial pressure of the reactant gas mixture (i.e., the combined partial pressure of the hydrogen containing gas and the oxygen containing gas) is controlled to ensure safe reaction conditions. According to the present invention, chamber 613 is backfilled with process gas such that the partial pressure of the reactant gas mixture is less than the partial pressure at which spontaneous combustion of the entire volume of the desired concentration ratio of reactant gas will not produce a detonation pressure wave of a predetermined amount. The predetermined amount is the amount of pressure that chamber 613 can reliably handle without failing. According to the present invention, insitu moisture generation is preferably carried out in a reaction chamber that can reliably handle a detonation pressure wave of four atmospheres or more without affecting its integrity. In such a case, reactant gas concentrations and operating partial pressure preferably do not provide a detonation wave greater than two atmospheres for the spontaneous combustion of the entire volume of the chamber.

By controlling the chamber partial pressure of the reactant gas mixture in the present invention any concentration ratio of hydrogen containing gas and oxygen containing gas can be used including hydrogen rich mixtures utilizing H2/O2 ratios greater than 2:1, respectively, and oxygen rich mixtures using H₂/O₂ ratios less than 0.5:1, respectively. The ability to use any concentration ratio of oxygen containing gas and hydrogen containing gas enables one to produce an ambient with any desired concentration ratio of H₂/H₂O or any concentration ratio of O₂/H₂O desired. Whether the ambient is oxygen rich or dilute steam or hydrogen rich or dilute steam can greatly affect device electrical characteristics. The present invention enables a wide variety of different steam ambients to be produced and therefore a wide variety of different anneal processes to be implemented.

In some anneal processes, an ambient having a low steam concentration with the balance O₂ (e.g., 20-30% H₂O/80-70% O₂) may be desired. Such an ambient can be formed by utilizing a reactant gas mixture comprising between 1-33% H₂ and the remainder O₂. A preferred embodiment of the present invention utilizes a reactant gas mix comprising 10% H₂ and 90% O₂. In other processes, an ambient of hydrogen rich steam (70-80% H₂/30-20% H₂O) may be desired. A hydrogen rich, low steam concentration ambient can be produced according to the present invention by utilizing a reactive gas mix comprising between 5-20% O₂ with the remainder H₂ (95-80%). It is to be appreciated that in the present invention any ratio of hydrogen containing gas and oxygen containing gas may be utilized because the heated wafer provides a continual ignition source to drive the reaction. Unlike pyrogenic torch methods, the present invention is not restricted to specific gas ratios necessary to keep a stable flame burning. The process gas mix can be provided into the reaction chamber at a flow rate between 1-20 SLM.

Next, as set forth in block 608, power to lamps 519 is increased so as to ramp up the temperature of wafer 561 to process temperature. Wafer 561 is preferably ramped from the stabilization temperature to process temperature at a rate of between 10-100° C./sec with 50° C./sec being preferred. The preferred process temperature of the present invention can be between 600-1200° C. and preferably at least 900° C. The process temperature must be at least the reaction temperature (i.e., must be at least the temperature at which the reaction between the oxygen containing gas and the hydrogen containing gas can be initiated by wafer 561) which is typically at least 600° C. It is to be noted that the actual reaction temperature depends upon the partial pressure of the reactant gas mixture as well as on the concentration ratio of the reactant gas mixture, and can be between 400° C. to 1250° C.

As the temperature of wafer 561 is ramped up to process temperature, it passes through the reaction temperature and causes the reaction of the hydrogen containing gas and the oxygen containing gas to form moisture or steam (H₂O). Since rapid thermal heating apparatus 500 is a “cold wall” reactor, the only sufficiently hot surfaces in chamber 513 to initiate the reaction is the wafer 561 and support ring 562. As such, in the present invention the moisture generating reaction occurs near, about 1 cm from, the surface of wafer 561. In the present invention the moisture generating reaction is confined to within about two inches of the wafer, or about the amount at which support ring 562 extends past the outside edge of wafer 561. Since it is the temperature of the wafer (and support ring) which initiates or turns “on” the moisture generation reaction, the reaction is said to be thermally controlled by the temperature of wafer 561 (and support ring 562). Additionally, the vapor generation reaction of the present invention is said to be “surface catalyzed” because the heated surface of the wafer is necessary for the reaction to occur, however, it is not consumed in the reaction which forms the water vapor.

In an alternative to first back filling the chamber with the process gas and then raising the wafer temperature to the reaction temperature, the wafer temperature can be first raised to the desired reaction temperature in step 608 and then the flow of process gas in step 606 provided into the chamber. The reaction of the hydrogen containing gas and oxygen containing gas preferably occurs at a reduced chamber pressure, and preferably at a pressure less than 30 torr, because it is thought that at reduced pressures more atomic oxygen is created, which improves the efficiency of the anneal. In an embodiment of the present invention, the reaction of the hydrogen containing gas and oxygen containing gas, and therefore the anneal occurs at a chamber pressure between 515 15 torr and ideally at 10 torr.

Next, as set forth in block 610, once the desired process temperature has been reached, the temperature of wafer 561 is held constant for a sufficient period of time to enable the ambient generated from the reaction of the hydrogen containing gas and the oxygen containing gas to anneal the oxide film. Wafer 561 will typically be held at process temperature for between 30-120 seconds. Process time and temperature are generally dictated by the thickness and type of the oxide film being annealed, the purpose of the oxidation, and the type and concentrations of the process gasses.

Next, as set forth in block 612, power to lamps 519 is reduced or turned off to reduce the temperature of wafer 561. The temperature of wafer 561 decreases (ramps down) as fast as it is able to cool down (at about 50° C./sec.). Simultaneously, N2 purge gas is fed into the chamber 513. The ISSG generation reaction ceases when wafer 61 and support ring 562 drop below the reaction temperature. Again it is the wafer temperature (and support ring) which dictates when the moisture reaction is turned “on” or “off”.

Next, as set forth in block 614, chamber 513 is pumped down, preferably below 1 torr, to ensure that no residual oxygen containing gas and hydrogen containing gas are present in chamber 513. The chamber is then backfilled with N₂ gas to the desired transfer pressure of approximately 20 torr and wafer 561 transferred out of chamber 513 to complete the anneal process. At this time a new wafer may be transferred into chamber 513 and the process set forth in flow chart 600 repeated.

We claim:

1. A method of annealing an oxide film comprising:
exposing an oxide film on a substrate to atomic oxygen (O) atoms for a predetermined period of time in a chamber.

2. The method of claim 1 wherein said atomic oxygen (O) atoms are formed by reacting a hydrogen containing gas and an oxygen containing gas together in said chamber.

3. The method of claim 2 wherein said hydrogen containing gas is hydrogen (H₂) and said oxygen containing gas is oxygen gas (O₂).

4. The method of claim 3 wherein said reaction is carried out with a gas mix comprising between 1-33% H₂ and the remainder O₂.

5. The method of claim 2 wherein said hydrogen containing gas and said oxygen containing gas are reacted together at a pressure between 5-15 torr.

6. The method of claim 1 wherein said atomic oxygen (O) atoms are formed by utilizing heat from a substrate to thermally decompose nitrous oxide (N₂O) gas near the surface of said oxide film.

7. The method of claim 6 wherein said substrate is heated to a temperature greater than 600° C. to thermally decompose said nitrous oxide (N₂O) gas.

8. The method of claim 1 wherein said atomic oxygen (O) atoms are formed near the surface of said oxide film by utilizing ultraviolet (UV) excitation of an oxygen containing gas near the surface of said oxide film.

9. The method of claim 8 wherein said oxygen containing gases are selected from the group consisting of oxygen gas (O₂) and nitrous oxide (N₂O) gas.

10. The method of claim 1 wherein said oxide film is exposed to said atomic oxygen (O) atoms at a substrate temperature greater than 600° C.

11. The method of claim 1 wherein said predetermined time is greater than 30 seconds.

12. The method of claim 2 wherein said reaction occurs within a distance from said oxide film which is less than or equal to the average lifetime of atomic oxygen in said ambient during operating conditions.

13. A method of forming an oxide film comprising:
depositing an oxide film over a substrate; and
exposing said oxide film to an ambient formed by reacting an oxygen containing
gas and a hydrogen containing gas in said chamber containing said substrate.

14. The method of claim 13 wherein said oxygen containing gas and said hydrogen containing gas are reacted together at a pressure of less than or equal to 150 torr.

15. The method of claim 13 wherein the pressure during said reaction is less than or equal to 30 torr.

16. The method of claim 13 wherein said oxygen containing gas is oxygen gas (O₂).

17. The method of claim 13 wherein said oxygen containing gas is nitric oxide (N₂O).

18. The method of claim 13 wherein said hydrogen containing gas is hydrogen gas (H₂).

19. The method of claim 13 wherein said hydrogen containing gas is ammonia (NH₃).

20. The method of claim 13 wherein said oxide film is a high temperature oxide (HTO) formed by chemical vapor deposition utilizing a silicon containing source gas and oxygen containing source gas at a temperature between 700-800° C.

21. The method of claim 13 wherein said oxide film is a low temperature is a low temperature oxide (LTO) formed at a deposition temperature between 375-450° C. utilizing a silicon containing source gas and oxygen containing source gas.

22. The method of claim 20 wherein said silicon containing source gas is selected from the group consisting of silane (SiH₄) and dichlorosilane (SiH₂Cl₂).

23. The method of claim 21 wherein said silicon containing gas is selected from the group consisting of silane (SiH₄) and disilane (Si₂H₆).

24. A method of forming a composite dielectric film over a substrate comprising:
depositing an oxide film over a substrate;
exposing said oxide film to an ambient formed by reacting a hydrogen containing gas and an oxygen containing gas near the surface of said oxide film; and
forming a silicon nitride film on said ambient exposed silicon oxide film.

25. The method of claim 24 further comprising depositing a second silicon oxide film on said silicon nitride film.

26. The method of claim 25 further comprising exposing said second silicon oxide film to an ambient formed by reacting a hydrogen containing gas and an oxygen containing gas near said second silicon oxide film.

27. A method of forming a nonvolatile memory comprising:
forming a floating gate on a tunnel dielectric formed on a single
crystalline silicon substrate;
depositing a first oxide film on said floating gate;
exposing said first oxide film to an ambient formed by reacting a
hydrogen containing gas and an oxygen containing gas near the surface of said first oxide film;
depositing a silicon nitride film on said ambient exposed silicon oxide film;
depositing a second silicon oxide film on said silicon nitride film;
forming a control gate on said second silicon oxide film; and
forming a pair of source/drain regions in said substrate on opposite side of said floating gate electrode.

28. The method of claim 26 further comprising prior to forming said control gate, exposing said second silicon oxide film to a second ambient formed by reacting an oxygen containing gas and a hydrogen containing gas together near the surface of said second silicon oxide film.

29. A method of forming a composite dielectric film over a substrate comprising:
depositing an oxide film over a substrate;
exposing said oxide film to an ambient formed by thermally decomposing N₂O gas near the surface of said oxide film; and
forming a silicon nitride film on said ambient exposed silicon oxide film.

30. The method of claim 29 further comprising depositing a second silicon oxide film on said silicon nitride film.

31. The method of claim 30 further comprising exposing said second silicon oxide film to an ambient formed by thermally decomposing N₂O gas near said second silicon oxide film.

32. A method of forming a nonvolatile memory comprising:
forming a floating gate on a tunnel dielectric formed on a single
crystalline silicon substrate;
depositing a first oxide film on said floating gate;
exposing said first oxide film to an ambient formed by thermally decomposing N₂O gas near the surface of said first oxide film;
depositing a silicon nitride film on said ambient exposed silicon oxide film;
depositing a second silicon oxide film on said silicon nitride film;
forming a control gate on said second silicon oxide film; and
forming a pair of source/drain regions in said substrate on opposite side of said floating gate electrode.

33. The method of claim 32 further comprising prior to forming said control gate, exposing said second silicon oxide film to a second ambient formed by thermally decomposing N₂O gas near the surface of said second silicon oxide film.
